(19) United States
(12) Patent Application Publication
(10) Pub. No.: US 2025/0350262 A1
(43) Pub. Date: Nov. 13, 2025

(54) FILTER DEVICE AND MULTIPLEXER

(71) Applicant: Murata Manufacturing Co., Ltd., Nagaokakyo-shi (JP)

(72) Inventor: Toshiaki TAKATA, Nagaokakyo-shi (JP)

(21) Appl. No.: 19/169,154

(22) Filed: Apr. 3, 2025

(30) Foreign Application Priority Data
May 9, 2024 (JP) 2024-076607

(51) Int. Cl. H03H 9/56; H04B 1/00

(52) U.S. Cl. CPC H03H 9/568; H04B 1/0057

(57) ABSTRACT

A filter device includes an input terminal, an output terminal, series arm resonators, and at least one parallel arm resonator. Each resonator is an acoustic wave resonator including an IDT electrode including electrode fingers on a piezoelectric substrate. The series and parallel arm resonators each include an intersecting region where adjacent electrode fingers overlap with each other in an electrode finger orthogonal direction. An average value of a duty ratio of the IDT electrode of a series arm resonator closest to the input terminal side is smaller than an average of average values of the duty ratios of the IDT electrodes of the other series arm resonators. An aspect ratio, obtained by dividing an intersecting width by a number of the electrode fingers, of the series arm resonator closest to the input terminal side is smaller than an average of the aspect ratios of the other series arm resonators.

### CROSS REFERENCE TO RELATED APPLICATIONS

This application claims the benefit of priority to Japanese Patent Application No. 2024-076607 filed on May 9, 2024. The entire contents of this application are hereby incorporated herein by reference.

### BACKGROUND OF THE INVENTION

### 1. Field of the Invention

The present invention relates to filter devices and multiplexers, the filter devices including acoustic wave resonators.

### 2. Description of the Related Art

Conventionally, filter devices including acoustic wave resonators have been widely used as filters of cellular phones, and the like. Japanese Unexamined Patent Application Publication No. 2016-54393 discloses an example of a ladder filter. In such a ladder filter, the duty ratio of the IDT (Interdigital Transducer) electrode of a series arm resonator having the smallest electrostatic capacitance, among a plurality of series arm resonators, is the smallest among the duty ratios of the IDT electrodes of the plurality of series arm resonators. The electrode finger pitch of the IDT electrode of the series arm resonator having the smallest electrostatic capacitance, among the plurality of series arm resonators, is the widest among the electrode finger pitches of the IDT electrodes of the plurality of series arm resonators.

Japanese Unexamined Patent Application Publication No. 2016-54393 describes that the power consumption of a series arm resonator can be reduced by reducing the duty ratio of the IDT electrode of the series arm resonator. By using such an effect, the electric power handling capability is increased without increasing the electrostatic capacitance of the series arm resonator.

### SUMMARY OF THE INVENTION

However, if the duty ratio of the IDT electrode of a series arm resonator is simply reduced, as in the ladder filter described in Japanese Unexamined Patent Application Publication No. 2016-54393, there is a possibility that heat will not be sufficiently dissipated from the center of the IDT electrode to the outside. In such a case, the series arm resonator may be locally damaged. Therefore, there is a possibility that the electric power handling capability of the ladder filter as a whole, or the electric power handling capability of the multiplexer including the ladder filter as a whole, may be insufficient.

Example embodiments of the present invention provide filter devices and multiplexers each capable of increasing an electric power handling capability.

A filter device according to an example embodiment of the present invention includes an input terminal and an output terminal, a plurality of series arm resonators, and at least one parallel arm resonator. The series arm resonators and the at least parallel arm resonator are each an acoustic wave resonator including an IDT electrode on a piezoelectric substrate, and each IDT electrode includes a plurality of electrode fingers. In each IDT electrode, a direction in which the plurality of electrode fingers extend is an electrode finger extension direction, and a direction orthogonal to the electrode finger extension direction is an electrode finger orthogonal direction, and the series arm resonators and the at least parallel arm resonator each include an intersecting region where adjacent electrode fingers overlap with each other when viewed in the electrode finger orthogonal direction. Among the plurality of series arm resonators, an average value of a duty ratio of the IDT electrode of one of the plurality of series arm resonators closest to the input terminal side in a circuit configuration is smaller than a value obtained by averaging the average values of the duty ratios of the IDT electrodes of all of the other series arm resonators. When a dimension of the intersecting region in the electrode finger orthogonal direction is defined as an intersecting width and a value obtained by dividing the intersecting width by a number of the plurality of electrode fingers is defined as an aspect ratio, among the plurality of series arm resonators, the aspect ratio of the one of the plurality of series arm resonators closest to the input terminal side in the circuit configuration is smaller than a value obtained by averaging the aspect ratios of all of the other series arm resonators.

A multiplexer according to an example embodiment of the present invention includes a plurality of filter devices including at least one transmission filter, which is the filter device according to another example embodiment of the present invention.

With the filter devices and the multiplexers according to example embodiments of the present invention, the electric power handling capability is increased.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a multiplexer according to a first example embodiment of the present invention.

FIG. 2 is a simplified plan view showing an electrode configuration of the multiplexer according to the first example embodiment of the present invention.

FIG. 3 is a schematic plan view of a series arm resonator in a first filter device in the first example embodiment of the present invention.

FIG. 4 is a simplified plan view showing an electrode configuration of a multiplexer of a comparative example.

FIG. 5 is a diagram showing a temperature distribution of the multiplexer according to the first example embodiment of the present invention when electric power is applied to the multiplexer.

FIG. 6 is a diagram showing a temperature distribution of the multiplexer of the comparative example when electric power is applied to the multiplexer.

FIG. 7 is a graph showing the attenuation frequency characteristics of the first filter device in the first example embodiment of the present invention and the comparative example.

FIG. 8 is a graph showing distributions of the duty ratio and the electrode finger pitch of the IDT electrode of a series arm resonator closest to an input terminal side in the circuit configuration, among a plurality of series arm resonators in the first example embodiment.

FIG. 9 is a schematic plan view of a series arm resonator in a first filter device in a second example embodiment of the present invention.

FIG. 10 is a graph showing distributions of the duty ratio and the normalized electrode finger pitch of the IDT electrode of a series arm resonator closest to an input terminal side in the circuit configuration, among a plurality of series arm resonators in the second example embodiment of the present invention.

FIG. 11 is a schematic plan view of a series arm resonator in a first filter device in a third example embodiment of the present invention.

FIG. 12 is a graph showing distributions of the duty ratio and the normalized electrode finger pitch of the IDT electrode of a series arm resonator closest to an input terminal side in the circuit configuration, among a plurality of series arm resonators in the third example embodiment of the present invention.

### DETAILED DESCRIPTION OF THE EXAMPLE EMBODIMENTS

The present invention will be clarified below by describing specific example embodiments of the present invention with reference to the drawings.

It should be noted that each example embodiment described in the present description is exemplary, and partial substitution or combination of configurations between different example embodiments is possible.

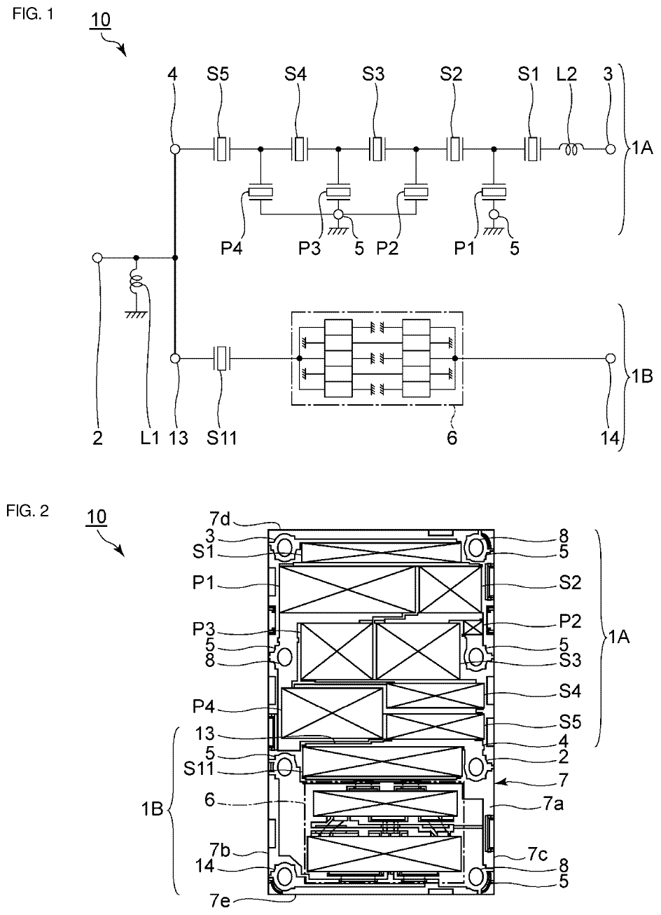

FIG. 1 is a circuit diagram of a multiplexer according to a first example embodiment of the present invention.

A multiplexer 10 according to the present example embodiment is a duplexer. The multiplexer 10 has a common connection terminal 2, a first filter device 1A, a second filter device 1B, and an inductor L1. The first filter device 1A is a filter device according to an example embodiment of the present invention. The first filter device 1A and the second filter device 1B are commonly connected to the common connection terminal 2. The common connection terminal 2 is an antenna terminal in the present example embodiment. The antenna terminal is connected to an antenna.

The inductor L1 is connected between the common connection terminal 2 and a reference potential. The inductor L1 is an inductor for impedance adjustment. Note that the inductor L1 does not necessarily have to be provided.

The first filter device 1A is a transmission filter of Band 12. That is, the pass band of the first filter device 1A is 699 MHz to 716 MHz, for example. The second filter device 1B is a reception filter of Band 12, for example. That is, the pass band of the second filter device 1B is 729 MHz to 746 MHz, for example. However, the pass bands of the first filter device 1A and the second filter device 1B are not limited to those described above.

Each of the first filter device 1A and the second filter device 1B may be a transmission filter or a reception filter. For example, both of the first filter device 1A and the second filter device 1B may be transmission filters or reception filters.

Note that multiplexers according to example embodiments of the present invention are not limited to duplexers. Therefore, the number of filter devices in the multiplexers according to example embodiments of the present invention is not limited to two. The multiplexers according to example embodiments of the present invention may alternatively be, for example, a triplexer, a quadplexer, or the like. It is sufficient that at least one filter device among the plurality of filter devices in a multiplexer according to an example embodiment of the present invention is a filter device according to an example embodiment of the present invention.

The specific configuration of the multiplexer 10 of the present example embodiment will be described below. The first filter device 1A of the multiplexer 10 includes an input terminal 3, an output terminal 4, a plurality of resonators, a reference potential terminal 5, and an inductor L2. The reference potential terminal 5 is a terminal connected to the reference potential.

The first filter device 1A is a ladder filter. The plurality of resonators of the first filter device 1A include a plurality of series arm resonators and a plurality of parallel arm resonators. In the present example embodiment, all of the resonators of the first filter device 1A are acoustic wave resonators.

Specifically, the plurality of series arm resonators of the first filter device 1A are a series arm resonator S1, a series arm resonator S2, a series arm resonator S3, a series arm resonator S4, and a series arm resonator S5. The plurality of series arm resonators are connected in series between the input terminal 3 and the output terminal 4. More specifically, the series arm resonator S1, the series arm resonator S2, the series arm resonator S3, the series arm resonator S4, and the series arm resonator S5 are arranged in this order in the circuit configuration from the input terminal 3 side. The inductor L2 is connected between the input terminal 3 and the series arm resonator S1.

Specifically, the plurality of parallel arm resonators of the first filter device 1A are a parallel arm resonator P1, a parallel arm resonator P2, a parallel arm resonator P3, and a parallel arm resonator P4. The parallel arm resonator P1 is connected between a connection point between the series arm resonators S1 and S2 and the reference potential terminal 5. The parallel arm resonator P2 is connected between a connection point between the series arm resonators S2 and S3 and the reference potential terminal 5. The parallel arm resonator P3 is connected between a connection point between the series arm resonators S3 and S4 and the reference potential terminal 5. The parallel arm resonator P4 is connected between a connection point between the series arm resonators S4 and S5 and the reference potential terminal 5. Note that the parallel arm resonator P2, the parallel arm resonator P3, and the parallel arm resonator P4 are commonly connected to the same reference potential terminal 5.

In the first filter device 1A, among all of the resonators, the series arm resonator S1 is closest to the input terminal 3 side in the circuit configuration. However, the circuit configuration of the first filter device 1A is not limited to that described above. Note that the inductor L2 does not have to be provided. It is sufficient that the first filter device 1A, as a filter device according to an example embodiment of the present invention, includes a plurality of series arm resonators and at least one parallel arm resonator.

The second filter device 1B of the multiplexer 10 includes an input terminal 13 and an output terminal 14, a plurality of resonators, and a plurality of reference potential terminals 5. Specifically, the plurality of resonators of the second filter device 1B are a series arm resonator S11 and a longitudinally coupled resonator-type acoustic wave filter 6. The number of stages of the longitudinally coupled resonator-type acoustic wave filter 6 is two. Each stage of the longitudinally coupled resonator-type acoustic wave filter 6 includes five IDT electrodes, for example. However, the number of stages and the number of IDT electrodes of the longitudinally coupled resonator-type acoustic wave filter 6 are not limited to those described above.

The longitudinally coupled resonator-type acoustic wave filter 6 is connected between the input terminal 13 and the output terminal 14. The series arm resonator S11 is connected between the input terminal 13 and the longitudinally coupled resonator-type acoustic wave filter 6. The circuit configuration of the second filter device 1B is not limited to that described above.

FIG. 2 is a simplified plan view showing an electrode configuration of the multiplexer according to the first example embodiment. In FIG. 2, the acoustic wave resonators are shown by schematic diagrams each obtained by adding two diagonal lines to a rectangle. In FIG. 2, each stage of the longitudinally coupled resonator-type acoustic wave filter 6 is shown by a schematic diagram obtained by adding two diagonal lines to a rectangle. The same goes for the simplified plan views of other drawings than FIG. 2.

The multiplexer 10 includes a piezoelectric substrate 7. The piezoelectric substrate is a substrate having piezoelectricity. In the present example embodiment, the piezoelectric substrate 7 is a substrate made of only a piezoelectric material. For example, lithium tantalate, lithium niobate, zinc oxide, aluminum nitride, quartz, PZT (lead zirconate titanate) or the like can be used as the piezoelectric material. In the present example embodiment, lithium niobate is used as the piezoelectric material. Note that the piezoelectric substrate 7 may alternatively be a laminated substrate including a piezoelectric layer.

In the present example embodiment, all of the resonators of the first filter device 1A share the same piezoelectric substrate 7. All of the resonators of the second filter device 1B share the same piezoelectric substrate 7. All of the resonators of the first filter device 1A and all of the resonators of the second filter device 1B share the same piezoelectric substrate 7. Note that, for example, the first filter device 1A and the second filter device 1B may alternatively have separate piezoelectric substrates 7.

The common connection terminal 2 of the multiplexer 10, the input terminal 3 of the first filter device 1A, the output terminal 14 of the second filter device 1B, and the plurality of reference potential terminals 5 are electrode pads provided on the piezoelectric substrate 7. On the other hand, the output terminal 4 of the first filter device 1A and the input terminal 13 of the second filter device 1B are configured as wiring lines. The output terminal 4 and the input terminal 13 are connected to the common connection terminal 2. Note that each terminal may be configured as an electrode pad or a wiring line.

The multiplexer 10 includes a plurality of bumps 8. The plurality of bumps 8 are provided on the piezoelectric substrate 7. Specifically, each bump 8 is provided on the electrode pad. More specifically, each bump 8 is provided on the common connection terminal 2, the input terminal 3, the output terminal 14, and the reference potential terminal 5. The plurality of bumps 8 are electrically connected to the outside.

The plurality of resonators of the first filter device 1A and the plurality of resonators of the second filter device 1B are each configured by providing an IDT electrode on the piezoelectric substrate 7. The plurality of series arm resonators and the plurality of parallel arm resonators of the first filter device 1A and the series arm resonator S11 of the second filter device 1B are each an acoustic wave resonator having one IDT electrode. On the other hand, the longitudinally coupled resonator-type acoustic wave filter 6 of the second filter device 1B includes a plurality of IDT electrodes. A specific configuration of the acoustic wave resonator is shown below.

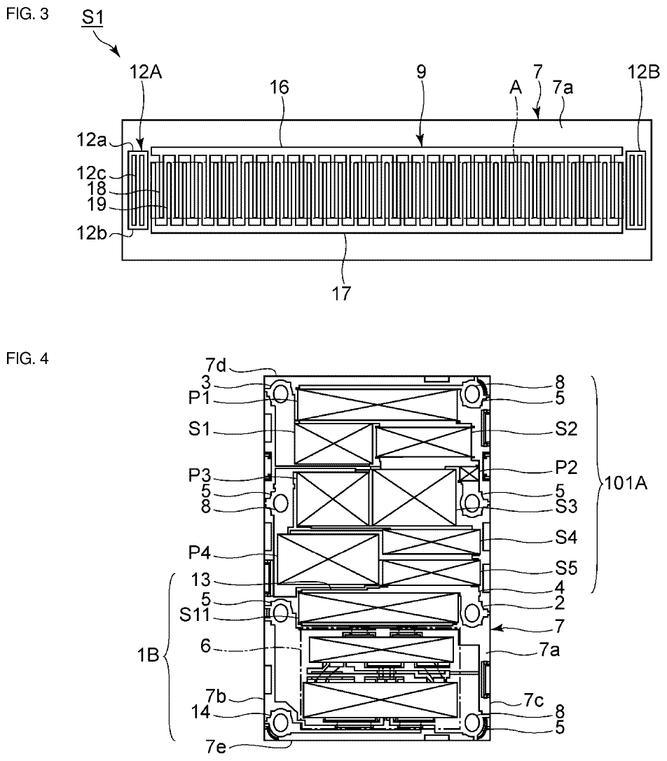

FIG. 3 is a schematic plan view of the series arm resonator in the first filter device in the first example embodiment. In FIG. 3, wiring lines and the like connected to the series arm resonator S1 are omitted.

An IDT electrode 9 of the series arm resonator S1 includes a pair of busbars and a plurality of electrode fingers. Specifically, the pair of busbars are a first busbar 16 and a second busbar 17. The first busbar 16 and the second busbar 17 face each other. Specifically, the plurality of electrode fingers are a plurality of first electrode fingers 18 and a plurality of second electrode fingers 19. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other. The first electrode fingers 18 and the second electrode fingers 19 are connected to different potentials. The IDT electrode 9 may include a single layer of metal film or a laminated metal film.

Hereinafter, the first electrode fingers 18 and the second electrode fingers 19 may be collectively referred to simply as electrode fingers. The first busbar 16 and the second busbar 17 may be collectively referred to simply as busbars. In the IDT electrode 9, the direction in which the plurality of electrode fingers extend is defined as an electrode finger extension direction, and the direction orthogonal to the electrode finger extension direction is defined as an electrode finger orthogonal direction.

The series arm resonator S1 includes an intersecting region A. Specifically, the intersecting region A is a region where adjacent electrode fingers overlap with each other when viewed in the electrode finger orthogonal direction. By applying an AC voltage to the IDT electrode 9, an acoustic wave is excited in the intersecting region A.

The series arm resonator S1 includes a pair of reflectors 12A and 12B. The reflectors 12A and 12B are provided on the piezoelectric substrate 7 so as to face each other and sandwich the IDT electrode 9 in the electrode finger orthogonal direction. The reflector 12A includes a pair of reflector busbars 12a and 12b, and a plurality of reflector electrode fingers 12c. In the reflector 12A, both ends of the plurality of reflector electrode fingers 12c are short-circuited by the pair of reflector busbars 12a and 12b. The reflector 12B is configured in the same manner as the reflector 12A.

Similar to the series arm resonator S1, each of the series arm resonators other than the series arm resonator S1 and each of the parallel arm resonators also includes an IDT electrode and a pair of reflectors, and includes an intersecting region. In the present example embodiment, the electrode finger extension direction and the electrode finger orthogonal direction are the same for all of the series arm resonators and all of the parallel arm resonators.

Here, the dimension of the intersecting region in the electrode finger orthogonal direction is defined as an intersecting width [μm]. A value obtained by dividing the intersecting width [μm] by the number [pieces] of the electrode fingers is defined as an aspect ratio [μm/piece]. In the present example embodiment, the IDT electrode of each series arm resonator is a so-called normal type IDT electrode. That is, the intersecting width of each IDT electrode is constant.

The plurality of series arm resonators in the first filter device 1A include series arm resonators having different aspect ratios [μm/piece]. Hereinafter, when comparing the aspect ratios [μm/piece], a value obtained by averaging the aspect ratios [μm/piece] of the plurality of series arm resonators may be used. In other words, such a value is obtained by dividing the sum of the aspect ratios [μm/piece] of the plurality of series arm resonators by the number of the plurality of series arm resonators.

The plurality of series arm resonators in the first filter device 1A include series arm resonators having different duty ratios. The duty ratio is a metallization ratio in a region of the IDT electrode where the plurality of electrode fingers are provided. Specifically, the duty ratio is the ratio of a portion covered by a metal on a virtual line of one wavelength extending in the electrode finger orthogonal direction in a region where the plurality of electrode fingers are provided. The metal here means the metal included in the electrode fingers.

When calculating the duty ratio, a wavelength defined by the electrode finger pitch of the IDT electrode may be used as a reference. Such a wavelength is referred to as “A”. The electrode finger pitch is the distance, in the electrode finger orthogonal direction, between the centers of electrode fingers connected to different potentials and adjacent to each other. Specifically, the electrode finger pitch of the IDT electrode 9 shown in FIG. 3 is the distance between the centers of the first electrode finger 18 and the second electrode finger 19. For example, when the electrode finger pitch is referred to as “p”, the equation λ=2p is satisfied.

In the present example embodiment, the duty ratio and the electrode finger pitch of the IDT electrode are constant in each series arm resonator. Note that the duty ratio and the electrode finger pitch of the IDT electrode do not have to be constant in each series arm resonator. Therefore, in the present description, the average value of the duty ratio of the IDT electrode may be used when comparing the parameters of the series arm resonators. Alternatively, a value obtained by averaging the average values of the duty ratios of the IDT electrodes of a plurality of series arm resonators may be used. In other words, such a value is obtained by dividing the sum of the average values of the duty ratios of the IDT electrodes of the plurality of series arm resonators by the number of the plurality of series arm resonators.

Unique features of the present example embodiment include the following configurations (1) and (2).
(1) The average value of the duty ratio of the IDT electrode 9 of the series arm resonator S1 is smaller than a value obtained by averaging the average values of the duty ratios of the IDT electrodes of all of the other series arm resonators.
(2) The aspect ratio [μm/piece] of the series arm resonator S1 is smaller than a value obtained by averaging the aspect ratios [μm/piece] of all of the other series arm resonators.

Thus, the electric power handling capability of the series arm resonator S1 is increased, and the electric power handling capability of the first filter device 1A as a whole is increased. As a result, the electric power handling capability of the multiplexer 10 as a whole is also increased.

Details of the effect that the electric power handling capability of the first filter device 1A as a whole is increased will be described below by comparing the first example embodiment with a comparative example.

FIG. 4 is a simplified plan view showing an electrode configuration of a multiplexer of the comparative example.

The comparative example differs from the first example embodiment in that it does not have the configuration (2) described above. The circuit configuration of the comparative example is the same as the circuit configuration of the first example embodiment. However, in the comparative example, among the plurality of series arm resonators, the aspect ratio [μm/piece] of the series arm resonator S1 closest to the input terminal side in the circuit configuration is larger than a value obtained by averaging the aspect ratios [μm/piece] of all of the other series arm resonators.

The temperature distribution when electric power is applied was compared between the first example embodiment and the comparative example. Specifically, such a temperature distribution is obtained when an electric power of 29 dBm is applied from the input terminal 3 at 716 MHZ, for example. This frequency is the highest frequency in the pass band of the first filter device 1A in the first example embodiment and a first filter device 101A in the comparative example. Therefore, when electric power is applied at 716 MHz, the electric power handling capability of the first filter device 1A and the first filter device 101A is the lowest.

In such a comparison, the design parameters of the first filter device 1A in the first example embodiment are as shown in Table 1. The design parameters of the first filter device 101A in the comparative example are as shown in Table 2. Note that the reference signs S1 to S5 in Tables 1 and 2 correspond to those of each series arm resonator in the first filter device.

TABLE 1

| | | | | | | Value obtained by averaging |
|---|---|---|---|---|---|---|
| | S1 | S2 | S3 | S4 | S5 | values in S2 to S5 |
| Duty ratio | 0.45 | 0.55 | 0.55 | 0.55 | 0.45 | 0.525 |
| Intersecting width [μm] | 67 | 164 | 202 | 84 | 88 | — |
| Number (pieces) of | 245 | 97 | 105 | 137 | 137 | — |
| electrode fingers | | | | | | |
| Aspect ratio [μm/piece] | 0.27 | 1.69 | 1.93 | 0.61 | 0.64 | 1.22 |

TABLE 2

| | | | | | | Value obtained by averaging |
|---|---|---|---|---|---|---|
| | S1 | S2 | S3 | S4 | S5 | values in S2 to S5 |
| Duty ratio | 0.45 | 0.55 | 0.55 | 0.55 | 0.45 | 0.525 |
| Intersecting width [μm] | 143 | 105 | 202 | 84 | 88 | — |
| Number (pieces) of | 115 | 151 | 105 | 137 | 137 | — |
| electrode fingers | | | | | | |
| Aspect ratio [μm/piece] | 1.24 | 0.70 | 1.93 | 0.61 | 0.64 | 0.97 |

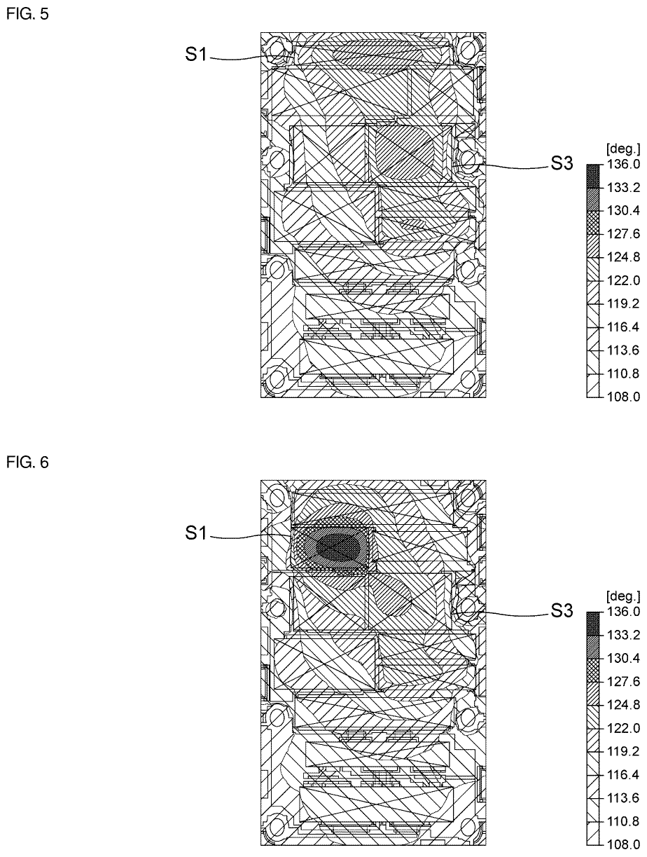

FIG. 5 is a diagram showing a temperature distribution of the multiplexer according to the first example embodiment when electric power is applied to the multiplexer. FIG. 6 is a diagram showing a temperature distribution of the multiplexer of the comparative example when electric power is applied to the multiplexer.

As shown in FIGS. 5 and 6, it can be seen that the highest temperature is lower in the first example embodiment than in the comparative example. Specifically, in the comparative example, the temperature is particularly high near the center of the series arm resonator S1. The highest temperature of the series arm resonator S1 of the comparative example is 135.2°. The temperature of the series arm resonator S3 of the comparative example is also higher than that of the other acoustic wave resonators. On the other hand, in the first example embodiment, the temperature of the series arm resonator S3 is the highest among the plurality of acoustic wave resonators. The highest temperature of the series arm resonator S3 of the first example embodiment is 127.3° C., for example. The temperature of the series arm resonator S1 of the first example embodiment is also higher than that of the other acoustic wave resonators, but is less than 127.3° C., for example.

In the first example embodiment and the comparative example, among the plurality of acoustic wave resonators, the series arm resonator S1 is closest to the input terminal 3 side in the circuit configuration. Therefore, when electric power is applied from the input terminal 3, a particularly large electric power is applied to the series arm resonator S1. Therefore, among the plurality of acoustic wave resonators, the series arm resonator S1 is particularly likely to generate heat. When electric power is applied to the IDT electrode of an acoustic wave resonator, the intensity of excitation is high near the center of the IDT electrode. From the above, it can be seen that the portion of the series arm resonator S1 near the center of the IDT electrode is particularly likely to generate heat.

As shown in Table 2, the aspect ratio [μm/piece] of the series arm resonator S1 of the comparative example is relatively large. Therefore, the intersecting width of the series arm resonator S1 is relatively wide. In such a case, the heat in the IDT electrode is difficult to be dissipated from the center of the IDT electrode to the outside. As a result, as shown in FIG. 6, the temperature of the series arm resonator S1 is particularly high.

In contrast, as shown in Table 1, in the first example embodiment, the aspect ratio [μm/piece] of the series arm resonator S1 is small, and the intersecting width is relatively narrow. Therefore, the heat generated near the center of the IDT electrode 9 easily reaches the pair of busbars. The heat is easily dissipated from the pair of busbars to the outside. In addition, in the series arm resonator S1, the number of electrode fingers is relatively large. Therefore, the dimension of the IDT electrode 9 of the series arm resonator S1 in the electrode finger orthogonal direction is relatively large. As a result, the portion where the intensity of excitation is high is dispersed in the electrode finger orthogonal direction, and the portion where heat is likely to be generated is dispersed in such a direction. Due to these synergistic effects, it is possible to reduce or prevent the temperature rise of the IDT electrode 9 of the series arm resonator S1.

In general, the higher the temperature of the IDT electrode, the stress migration is more likely to occur. As a result, the IDT electrode tends to be damaged. However, as described above, in the first example embodiment, the temperature rise of the IDT electrode 9 of the series arm resonator S1 due to the application of electric power is reduced or prevented. Thus, the electric power handling capability of the series arm resonator S1 is increased, and the electric power handling capability of the first filter device 1A as a whole is increased. As a result, the electric power handling capability of the multiplexer 10 as a whole is also increased.

Further, the attenuation frequency characteristics were compared between the first filter device 1A of the first example embodiment and the first filter device 101A of the comparative example. In such a comparison, the design parameters of the first filter device 1A in the first example embodiment and the design parameters of the first filter device 101A in the comparative example are as shown in Tables 1 and 2 described above.

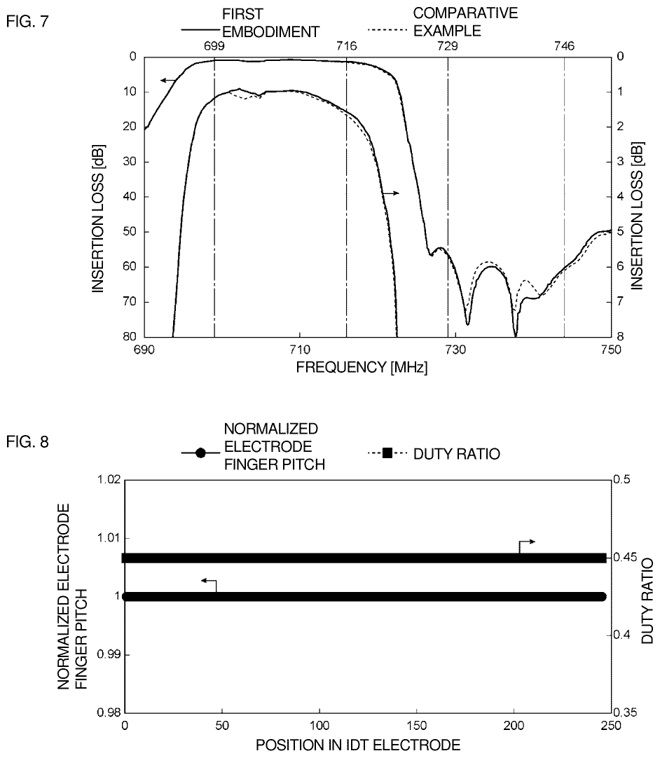

FIG. 7 is a graph showing the attenuation frequency characteristics of the first filter device in the first example embodiment and the comparative example.

As shown in FIG. 7, the pass band of the first filter device 1A in the first example embodiment and the first filter device 101A in the comparative example is 699 MHz to 716 MHZ, for example. It can be seen that the insertion loss in the pass band is smaller in the first example embodiment than in the comparative example. In the first example embodiment, the maximum value of the insertion loss in the pass band is 1.56 dB, for example. In the comparative example, the maximum value of the insertion loss in the pass band is 1.66 dB. Therefore, in the first example embodiment, the maximum value of the insertion loss in the pass band is smaller than in the comparative example.

In the first example embodiment, the aspect ratio [μm/piece] of the series arm resonator S1 is relatively small. Therefore, the intersecting width of the series arm resonator S1 is relatively narrow and the number of electrode fingers of the series arm resonator S1 is relatively large. Thus, the electrical resistance of the series arm resonator S1 is lowered, and the insertion loss is reduced.

A preferred configuration of the first example embodiment will be described below.

As shown in FIG. 1, it is preferable that, among all of the series arm resonators and all of the parallel arm resonators, only the series arm resonator S1 is closest to the input terminal 3 side in the circuit configuration. For example, among all of the series arm resonators and all of the parallel arm resonators, when the series arm resonator S1 and a parallel arm resonator are closest to the input terminal 3 side in the circuit configuration, a large electric power is applied to the parallel arm resonator. In addition, one end of the parallel arm resonator is connected to the input potential, and the other end is connected to the reference potential. Therefore, the potential difference between one end and the other end of the parallel arm resonator is particularly large. Therefore, the load on the parallel arm resonator is large.

In contrast, in the present example embodiment, among all of the series arm resonators and all of the parallel arm resonators, only the series arm resonator S1 is closest to the input terminal 3 side in the circuit configuration. Thus, the load on all of the parallel arm resonators is reduced. However, in an example embodiment of the present invention, among all of the series arm resonators and all of the parallel arm resonators, the series arm resonator S1 and a parallel arm resonator may be closest to the input terminal side in the circuit configuration. In such a case, as in the first example embodiment, the effect of increasing the electric power handling capability of the series arm resonator S1 is obtained. Therefore, the effect of increasing the electric power handling capability of the first filter device 1A as a whole and the multiplexer 10 as a whole is obtained.

As shown in FIG. 2, it is preferred that, among the plurality of series arm resonators, the IDT electrode 9 of the series arm resonator S1 closest to the input terminal 3 side in the circuit configuration is disposed between two of the plurality of bumps 8. With such a configuration, heat easily propagates from the IDT electrode 9 of the series arm resonator S1 to the two bumps 8. Thus, it is easy to dissipate heat to the outside of the multiplexer 10 via the bumps 8. Therefore, the temperature rise of the IDT electrode 9 of the series arm resonator S1 is effectively reduced or prevented.

It is preferable that acoustic wave resonator(s) adjacent to the series arm resonator S1 in the electrode finger extension direction of the series arm resonator S1 is/are acoustic wave resonator(s) other than a series arm resonator having the largest aspect ratio [μm/piece] among all of the series arm resonators. Specifically, in the present example embodiment, the acoustic wave resonator(s) adjacent to the series arm resonator S1 in the electrode finger extension direction of the series arm resonator S1 is/are the parallel arm resonator P1 and the series arm resonator S2. On the other hand, the acoustic wave resonator having the largest aspect ratio [μm/piece] among all of the acoustic wave resonators is the series arm resonator S3.

When the aspect ratio [μm/piece] of an acoustic wave resonator is large, the heat dissipation property of the acoustic wave resonator is low. Therefore, the heat dissipation property of the acoustic wave resonators other than the acoustic wave resonator having the largest aspect ratio [μm/piece] among all of the acoustic wave resonators is relatively high, so that the temperature of the IDT electrodes of such acoustic wave resonators is relatively low. When such series arm resonator(s) is/are adjacent to the series arm resonator S1, the heat dissipation from the IDT electrode 9 of the series arm resonator S1 is unlikely to be inhibited. Therefore, among the plurality of series arm resonators, the temperature rise of the IDT electrode 9 of the series arm resonator S1 closest to the input terminal 3 side in the circuit configuration is reduced or prevented more reliably.

It is more preferable that the acoustic wave resonator(s) adjacent to the series arm resonator S1 in the electrode finger extension direction of the series arm resonator S1 is/are the acoustic wave resonator(s) other than the series arm resonator having the largest aspect ratio [μm/piece] among all of the series arm resonators. Specifically, in the present example embodiment, the series arm resonator having the largest aspect ratio [μm/piece] among all of the series arm resonators is the series arm resonator S3.

The parallel arm resonators are connected to the reference potential terminal 5. Therefore, heat is easily dissipated from the parallel arm resonators to the outside of the multiplexer 10 via the reference potential terminal 5. On the other hand, heat dissipation property tends to be low in the series arm resonators. Therefore, the temperature of the IDT electrode of the series arm resonator S3 having the largest aspect ratio [μm/piece] among all of the series arm resonators tends to be particularly high. On the other hand, the temperature of the IDT electrodes of the acoustic wave resonators other than the series arm resonator S3 is relatively low.

From the above, it can be seen that when the acoustic wave resonator(s) adjacent to the series arm resonator S1 in the electrode finger extension direction of the series arm resonator S1 is/are acoustic wave resonator(s) other than the series arm resonator S3, the heat dissipation from the IDT electrode 9 of the series arm resonator S1 is unlikely to be inhibited. Therefore, among the plurality of series arm resonators, the temperature rise of the IDT electrode 9 of the series arm resonator S1 closest to the input terminal 3 side in the circuit configuration is reduced or prevented even more reliably.

It is preferable that the aspect ratio [μm/piece] of the series arm resonator S1 is the smallest among the aspect ratios [μm/piece] of all of the series arm resonators. Thus, the temperature rise of the IDT electrode 9 of the series arm resonator S1 is reduced or prevented more reliably.

It is preferable that the number of the plurality of electrode fingers of the IDT electrode 9 of the series arm resonator S1 is the largest among the number of the pluralities of electrode fingers of the IDT electrodes of all of the series arm resonators. In such a case, the aspect ratio [μm/piece] of the series arm resonator S1 is reduced more reliably. It is preferable that the intersecting width of the series arm resonator S1 is the narrowest among the intersecting widths of all of the series arm resonators. Also in such a case, the aspect ratio [μm/piece] of the series arm resonator S1 is reduced more reliably.

As shown in FIG. 2, the piezoelectric substrate 7 has a main surface 7a. The plurality of IDT electrodes and the plurality of reflectors of the plurality of resonators of the multiplexer 10 are provided on the main surface 7a. The shape of the main surface 7a is rectangular. Therefore, the main surface 7a includes a pair of long sides 7b and 7c, and a pair of short sides 7d and 7e.

It is preferred that, among the plurality of series arm resonators, the IDT electrode 9 of the series arm resonator S1 closest to the input terminal 3 side in the circuit configuration is located closer to the short side 7d side of the main surface 7a of the piezoelectric substrate 7 than all of the other IDT electrodes. In such a case, the IDT electrode 9 of the series arm resonator S1 is adjacent to other IDT electrode(s) only on one side in the electrode finger extension direction of the series arm resonator S1. The IDT electrode becomes a heat source when electric power is applied. With the above configuration, the heat source adjacent to the IDT electrode 9 of the series arm resonator S1 is reduced. Thus, the temperature rise of the IDT electrode 9 of the series arm resonator S1 is effectively reduced or prevented.

Incidentally, the series arm resonator S1 shown in FIG. 1 may alternatively be, for example, one of two or more split-type series arm resonators. In such a case, the split-type series arm resonator(s) other than the series arm resonator S1 is/are connected between the series arm resonator S1 and the series arm resonator S2. That is, among all of the series arm resonators including the split-type series arm resonators, the series arm resonator S1 is closest to the input terminal 3 side in the circuit configuration.

It is sufficient that the average value of the duty ratio of the IDT electrode 9 of the series arm resonator S1 is smaller than a value obtained by averaging the average values of the duty ratios of the IDT electrodes of all of the other series arm resonators including the split-type series arm resonator(s). It is sufficient that the aspect ratio [μm/piece] of the series arm resonator S1 is smaller than a value obtained by averaging the aspect ratios [μm/piece] of all of the other series arm resonators including the split-type series arm resonator(s). Thus, the electric power handling capability of the series arm resonator S1 is increased.

FIG. 8 is a graph showing distributions of the duty ratio and the electrode finger pitch of the IDT electrode of the series arm resonator closest to the input terminal side in the circuit configuration, among the plurality of series arm resonators in the first example embodiment. The horizontal axis in FIG. 8 indicates the position of the IDT electrode 9 of the series arm resonator S1, based on the arrangement of the electrode fingers.

Specifically, the value of the horizontal axis indicates the position of the electrode finger of the IDT electrode 9 counted from one end in the electrode finger orthogonal direction.

On the other hand, the vertical axis on the left side in FIG. 8 indicates the normalized electrode finger pitch of the IDT electrode 9 at each position. In the present description, the normalized electrode finger pitch is a value obtained by normalizing the electrode finger pitch of the IDT electrode 9 at each position by the average value of the electrode finger pitch of the IDT electrode 9. The horizontal axis and the vertical axis in FIGS. 10 and 12, which will be described later, are defined in the same way as in FIG. 8.

In the first example embodiment, the electrode finger pitch of the IDT electrode 9 of the series arm resonator S1 is constant. Therefore, the normalized electrode finger pitch is 1 over the entire IDT electrode 9. The duty ratio of the IDT electrode 9 is constant. Specifically, the duty ratio of the IDT electrode 9 is about 0.45, for example. Note that the duty ratio of the IDT electrode 9 is not limited to the value described above.

In an example embodiment of the present invention, the duty ratio and the electrode finger pitch of the IDT electrode 9 do not have to be constant. Examples in which the duty ratio and the electrode finger pitch of the IDT electrode 9 are not constant are shown in a second example embodiment and a third example embodiment. Note that the circuit configurations of the second example embodiment and the third example embodiment are the same as the circuit configuration of the first example embodiment. Therefore, in the descriptions of the second example embodiment and the third example embodiment, the reference signs of the components other than the series arm resonator S1 and its IDT electrode 9 are the same as those used in the description of the first example embodiment.

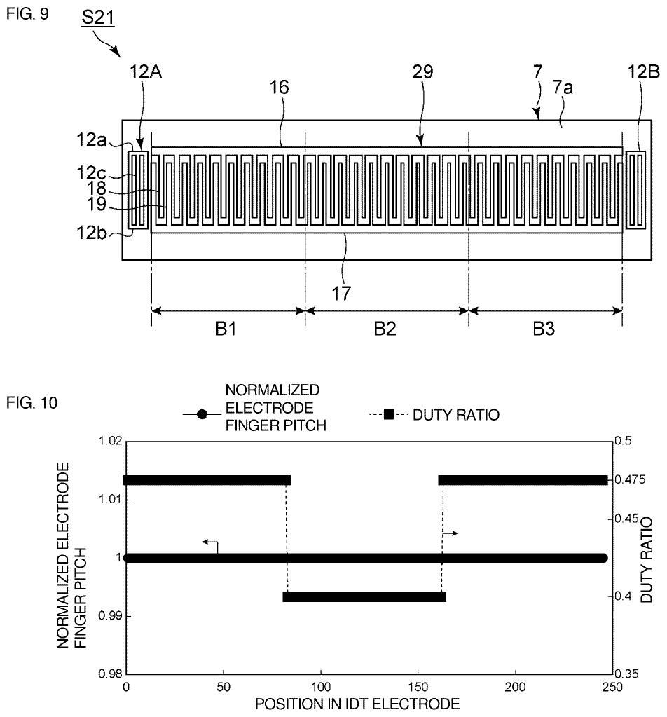

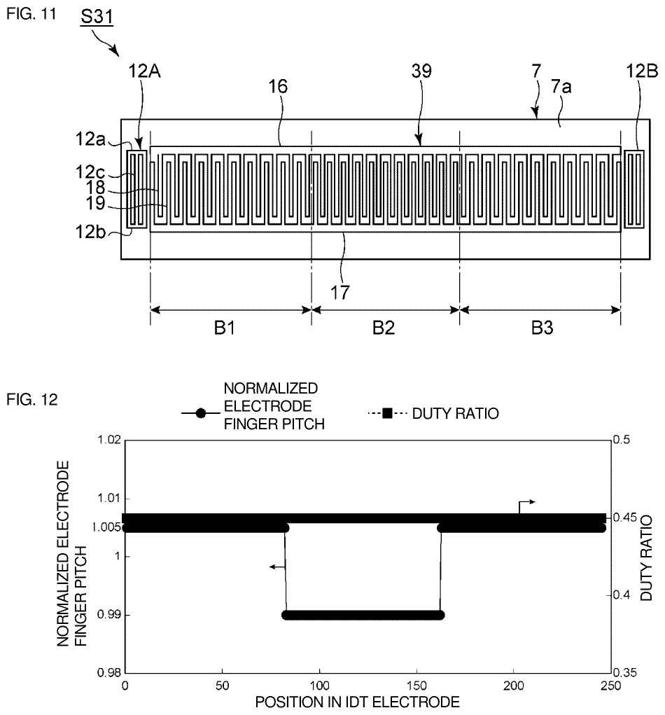

FIG. 9 is a schematic plan view of a series arm resonator in a first filter device in a second example embodiment. In FIG. 9, wiring lines and the like connected to the series arm resonator are omitted. The same goes for FIG. 11, which will be described later.

A series arm resonator S21 is the series arm resonator closest to the input terminal 3 side in the circuit configuration, among the plurality of series arm resonators. The present example embodiment differs from the first example embodiment in that the duty ratio of an IDT electrode 29 in the series arm resonator S21 is not constant. Except for the above point, the multiplexer of the present example embodiment has the same configuration as the multiplexer 10 of the first example embodiment. That is, in the present example embodiment, the electrode finger pitch of the IDT electrode 29 is constant.

The IDT electrode 29 of the series arm resonator S21 includes a first region B1, a second region B2, and a third region B3. These regions are obtained by dividing the IDT electrode 29 is into three regions in the electrode finger orthogonal direction. More specifically, the second region B2 is a central region of the IDT electrode 29 in the electrode finger orthogonal direction. The first region B1 and the third region B3 are both end regions of the IDT electrode 29 in the electrode finger orthogonal direction.

It should be noted that even in other example embodiments of the present invention than the second example embodiment, the IDT electrode corresponding to the IDT electrode 29 of the series arm resonator S21 includes a first region B1, a second region B2 and a third region B3. For example, in the first example embodiment shown in FIG. 3, the IDT electrode 9 of the series arm resonator S1 includes each of the above-described regions.

Returning to FIG. 9, in the IDT electrode 29 of the second example embodiment, the dimensions of the first region B1, the second region B2 and the third region B3 in the electrode finger orthogonal direction are the same or substantially the same. Note that example embodiments of the present invention are not limited to such a configuration. For example, the dimension of the first region B1 in the electrode finger orthogonal direction may be, for example, about 20% or more and about 40% or less of the dimension of the IDT electrode 29 in the electrode finger orthogonal direction. The same goes for the dimensions of the second region B2 and the third region B3 in the electrode finger orthogonal direction.

FIG. 10 is a graph showing distributions of the duty ratio and the electrode finger pitch of the IDT electrode of the series arm resonator closest to the input terminal side in the circuit configuration, among the plurality of series arm resonators d example embodiment of the present invention.

In each of the first region B1, second region B2 and third region B3 of the IDT electrode 29 of the series arm resonator S21, the duty ratio is constant. However, the duty ratio does not have to be constant in each region. Therefore, in the following description, when comparing the duty ratios between the regions of the IDT electrode 29, the average value of the duty ratio may be used.

In the IDT electrode 29, the average value of the duty ratio in the second region B2 is smaller than the average value of the duty ratio in the first region B1 and the average value of the duty ratio in the third region B3. More specifically, the average value of the duty ratio in the second region B2 is about 0.4, for example. The average value of the duty ratio in the first region B1 and the average value of the duty ratio in the third region B3 are both about 0.475, for example. The average value of the duty ratio in each region is not limited to the value described above.

In the second example embodiment, the electric power handling capability of the series arm resonator S21 is effectively increased. The reason for this will be explained below.

When electric power is applied to the IDT electrode 29, the intensity of excitation in the second region B2 is higher than the intensity of excitation in the first region B1 and the third region B3. Therefore, among the first region B1, the second region B2 and the third region B3, the second region B2 is more likely to generate heat. Consequently, stress migration is likely to occur in the second region B2 among the first region B1, the second region B2 and the third region B3.

In contrast, in the second region B2, the average value of the duty ratio is smaller than the average value of the duty ratio in the first region B1 and the average value of the duty ratio in the third region B3. Therefore, in the second region B2, the distance between the electrode fingers in the electrode finger orthogonal direction is longer. Thus, even if some of the electrode fingers are damaged due to stress migration, short-circuiting between the electrode fingers is reduced or prevented. Therefore, the electric power handling capability of the series arm resonator S21 is effectively increased. Thus, the electric power handling capability of the first filter device as a whole and the electric power handling capability of the multiplexer as a whole are effectively increased.

It is preferable that the dimensions of the first region B1, the second region B2 and the third region B3 in the electrode finger orthogonal direction are the same or substantially the same. Alternatively, it is preferable that the number of the electrode fingers included in the first region B1, the second region B2 and the third region B3 is substantially the same. With such a configuration, the electric power handling capability of the series arm resonator S21 is suitably increased.

FIG. 11 is a schematic plan view of a series arm resonator in a first filter device in a third example embodiment.

A series arm resonator S31 is the series arm resonator closest to the input terminal 3 side in the circuit configuration, among the plurality of series arm resonators. The present example embodiment differs from the first example embodiment in that the electrode finger pitch of an IDT electrode 39 in the series arm resonator S31 is not constant. Except for the above point, the multiplexer of the present example embodiment has the same configuration as the multiplexer 10 of the first example embodiment. That is, in the present example embodiment, the duty ratio of the IDT electrode 39 is constant.

In the IDT electrode 39, the number of the electrode fingers included in a first region B1, a second region B2, and a third region B3 is the same or substantially the same.

FIG. 12 is a graph showing distributions of the duty ratio and the normalized electrode finger pitch of the IDT electrode of the series arm resonator closest to the input terminal side in the circuit configuration, among the plurality of series arm resonators in the third example embodiment of the present invention.

In each of the first region B1, second region B2 and third region B3 of the IDT electrode 39 of the series arm resonator S31, the electrode finger pitch is constant. However, the electrode finger pitch does not have to be constant in each region. Therefore, in the following description, when comparing the electrode finger pitch between the regions of the IDT electrode 39, the average value of the electrode finger pitch may be used. In FIG. 12, the normalized electrode finger pitch is used as an index of the magnitude of the electrode finger pitch. In the following description, when comparing the electrode finger pitch between the regions of the IDT electrode 39, the average value of the normalized electrode finger pitch may also be used.

In the IDT electrode 39, the average value of the electrode finger pitch in the second region B2 is smaller than the average value of the electrode finger pitch in the first region B1 and the average value of the electrode finger pitch in the third region B3. More specifically, the average value of the normalized electrode finger pitch in the second region B2 is about 0.99, for example. The average value of the normalized electrode finger pitch in the first region B1 and the average value of the normalized electrode finger pitch in the third region B3 are both about 1.005, for example. The average value of the normalized electrode finger pitch in each region is not limited to the value described above.

In the present example embodiment, the electric power handling capability of the series arm resonator S31 is effectively increased. The reason for this will be explained below.

First, the narrower the electrode finger pitch of the IDT electrode of an acoustic wave resonator, the higher the resonant frequency of the acoustic wave resonator. In the series arm resonator S31 of the present example embodiment, the average value of the electrode finger pitch in the second region B2 of the IDT electrode 39 is smaller than the average value of the electrode finger pitch in the first region B1 and the average value of the electrode finger pitch in the third region B3. Therefore, the resonant frequency in the second region B2 is higher than the average value of the resonant frequency of the series arm resonator S31. Therefore, the intermediate frequency between the resonant frequency and the anti-resonant frequency in the second region B2 is higher than the intermediate frequency between the average value of the resonant frequency and the anti-resonant frequency of the series arm resonator S31.

The value of the intermediate frequency between the resonant frequency and the anti-resonant frequency is the average value of the resonant frequency and the anti-resonant frequency. Similarly, the value of the intermediate frequency between the average value of the resonant frequency and the anti-resonant frequency is a value obtained by averaging the average value of the resonant frequency and the anti-resonant frequency. In the following description, the intermediate frequency between the resonant frequency and the anti-resonant frequency and/or the intermediate frequency between the average value of the resonant frequency and the anti-resonant frequency may be described as “intermediate frequency”.

In an acoustic wave resonator, when the frequency at which electric power is applied is near the intermediate frequency between the resonant frequency and the anti-resonant frequency, the electric power handling capability is particularly low. This is because the intensity of excitation is particularly high near the intermediate frequency between the resonant frequency and the anti-resonant frequency.

Here, the frequency at which electric power is applied to the series arm resonator of the filter device is closer to the resonant frequency than to the anti-resonant frequency. That is, the frequency at which electric power is applied to the series arm resonator S31 of the present example embodiment is closer to the average value of the resonant frequency than to the anti-resonant frequency. In other words, the frequency at which electric power is applied to the series arm resonator S31 is lower than the intermediate frequency of the whole series arm resonator S31.

On the other hand, the intermediate frequency in the second region B2 of the IDT electrode 39 of the series arm resonator S31 is higher than the intermediate frequency of the whole series arm resonator S31. Therefore, in the second region B2, the intermediate frequency is effectively kept away from the frequency at which electric power is applied. Therefore, the intensity of excitation in the second region B2 is reduced or prevented from increasing.

On the other hand, the average value of the electrode finger pitch in the first region B1 is larger than the average value of the electrode finger pitch in the second region B2. Therefore, the resonant frequency in the first region B1 is lower than the average value of the resonant frequency of the series arm resonator S31. Therefore, the intermediate frequency in the first region B1 is lower than the intermediate frequency of the whole series arm resonator S31. From the above, it can be seen that, in the first region B1, the intermediate frequency tends to approach the frequency at which electric power is applied, and the intensity of excitation tends to be high. The same goes for the third region B3.

However, the first region B1 is not located in the center of the IDT electrode 39. Therefore, in the first region B1, the intensity of excitation is not high, and heat is less likely to be generated. Therefore, in the first region B1, even if the intensity of excitation becomes high due to the electrode finger pitch, the electric power handling capability is unlikely to decrease. The same goes for the third region B3. On the other hand, in the second region B2 located at the center of the IDT electrode 39, the increase of the intensity of excitation is reduced or prevented as described above. Thus, the heat generation in the second region B2 is reduced or prevented, and the electric power handling capability is increased.

As described above, the electric power handling capability of the series arm resonator S31 in the IDT electrode 39 is made nearly uniform, and the electric power handling capability of the series arm resonator S31 is effectively increased. Thus, the electric power handling capability of the first filter device as a whole and the electric power handling capability of the multiplexer as a whole are effectively increased.

Note that the series arm resonator S31 may have the configurations of both the present example embodiment and the second example embodiment described above.

It is preferable that the dimensions of the first region B1, the second region B2 and the third region B3 in the electrode finger orthogonal direction are the same or substantially the same. Alternatively, it is preferable that the number of electrode fingers included in the first region B1, the second region B2 and the third region B3 is the same or substantially the same. With such a configuration, the electric power handling capability of the series arm resonator S31 is suitably increased.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A filter device comprising:
an input terminal and an output terminal;
a plurality of series arm resonators; and
at least one parallel arm resonator;
wherein
the series arm resonators and the at least one parallel arm resonator are each an acoustic wave resonator including an IDT electrode on a piezoelectric substrate, and each IDT electrode includes a plurality of electrode fingers;
in each IDT electrode, a direction in which the plurality of electrode fingers extend is an electrode finger extension direction, and a direction orthogonal to the electrode finger extension direction is an electrode finger orthogonal direction, and the series arm resonators and the at least one parallel arm resonator each include an intersecting region where adjacent electrode fingers overlap with each other when viewed in the electrode finger orthogonal direction;
among the plurality of series arm resonators, an average value of a duty ratio of the IDT electrode of one of the series arm resonators closest to the input terminal side in a circuit configuration is smaller than a value obtained by averaging the average values of the duty ratios of the IDT electrodes of all of the other series arm resonators; and
when a dimension of the intersecting region in the electrode finger orthogonal direction is defined as an intersecting width and a value obtained by dividing the intersecting width by a number of the plurality of electrode fingers is defined as an aspect ratio, among the plurality of series arm resonators, the aspect ratio of the series arm resonator closest to the input terminal side in the circuit configuration is smaller than a value obtained by averaging the aspect ratios of all of the other series arm resonators.

2. The filter device according to claim 1, wherein among all of the series arm resonators and all of the at least one parallel arm resonator, only the one of the plurality of series arm resonators is closest to the input terminal side in the circuit configuration.

3. The filter device according to claim 1, wherein
a plurality of bumps are provided on the piezoelectric substrate; and
among the plurality of series arm resonators, the IDT electrode of the series arm resonator closest to the input terminal side in the circuit configuration is between two of the plurality of bumps.

4. The filter device according to claim 1, wherein
the piezoelectric substrate includes a main surface, a shape of the main surface is rectangular or substantially rectangular, the main surface includes a pair of long sides and a pair of short sides, and the plurality of IDT electrodes are provided on the main surface; and
among the plurality of series arm resonators, the IDT electrode of the series arm resonator closest to the input terminal side in the circuit configuration is closer to one of the short sides of the main surface of the piezoelectric substrate than all of the other IDT electrodes.

5. The filter device according to claim 1, wherein an acoustic wave resonator adjacent to the one of the plurality of series arm resonators closest to the input terminal side in the circuit configuration in the electrode finger extension direction of the series arm resonator is an acoustic wave resonator other than a series arm resonator with a largest aspect ratio among all of the series arm resonators.

6. The filter device according to claim 1, wherein among the plurality of series arm resonators, the aspect ratio of the series arm resonator closest to the input terminal side in the circuit configuration is smallest among the aspect ratios of all of the series arm resonators.

7. The filter device according to claim 1, wherein
among the plurality of series arm resonators, a number of the plurality of electrode fingers of the IDT electrode of the series arm resonator closest to the input terminal side in the circuit configuration is largest among numbers of the pluralities of electrode fingers of the IDT electrodes of all of the series arm resonators; and
among the plurality of series arm resonators, the intersecting width of the series arm resonator closest to the input terminal side in the circuit configuration is narrowest among the intersecting widths of all of the series arm resonators.

8. The filter device according to claim 1, wherein when the IDT electrode of one of the plurality of series arm resonators closest to the input terminal side in the circuit configuration is divided into three regions in the electrode finger orthogonal direction, the average value of the duty ratio in one central region is smaller than the average value of the duty ratio in two end regions.

9. The filter device according to claim 1, wherein when the IDT electrode of one of the plurality of series arm resonators closest to the input terminal side in the circuit configuration is divided into three regions in the electrode finger orthogonal direction, an average value of an electrode finger pitch in one central region is smaller than the average value of the electrode finger pitch in two end regions.

10. A multiplexer comprising:
a plurality of filter devices including at least one transmission filter device; wherein
the at least one transmission filter device is the filter device according to claim 1.

11. The multiplexer according to claim 10, wherein among all of the series arm resonators and all of the at least one parallel arm resonator, only the one of the plurality of series arm resonators is closest to the input terminal side in the circuit configuration.

12. The multiplexer according to claim 10, wherein
a plurality of bumps are provided on the piezoelectric substrate; and
among the plurality of series arm resonators, the IDT electrode of the series arm resonator closest to the input terminal side in the circuit configuration is between two of the plurality of bumps.

13. The multiplexer according to claim 10, wherein
the piezoelectric substrate includes a main surface, a shape of the main surface is rectangular or substantially rectangular, the main surface includes a pair of long sides and a pair of short sides, and the plurality of IDT electrodes are provided on the main surface; and
among the plurality of series arm resonators, the IDT electrode of the series arm resonator closest to the input terminal side in the circuit configuration is closer to one of the short sides of the main surface of the piezoelectric substrate than all of the other IDT electrodes.

14. The multiplexer according to claim 10, wherein an acoustic wave resonator adjacent to the one of the plurality of series arm resonators closest to the input terminal side in the circuit configuration in the electrode finger extension direction of the series arm resonator is an acoustic wave resonator other than a series arm resonator with a largest aspect ratio among all of the series arm resonators.

15. The multiplexer according to claim 10, wherein among the plurality of series arm resonators, the aspect ratio of the series arm resonator closest to the input terminal side in the circuit configuration is smallest among the aspect ratios of all of the series arm resonators.

16. The multiplexer according to claim 10, wherein
among the plurality of series arm resonators, a number of the plurality of electrode fingers of the IDT electrode of the series arm resonator closest to the input terminal side in the circuit configuration is largest among numbers of the pluralities of electrode fingers of the IDT electrodes of all of the series arm resonators; and
among the plurality of series arm resonators, the intersecting width of the series arm resonator closest to the input terminal side in the circuit configuration is narrowest among the intersecting widths of all of the series arm resonators.

17. The multiplexer according to claim 10, wherein when the IDT electrode of one of the plurality of series arm resonators closest to the input terminal side in the circuit configuration is divided into three regions in the electrode finger orthogonal direction, the average value of the duty ratio in one central region is smaller than the average value of the duty ratio in two end regions.

18. The multiplexer according to claim 10, wherein when the IDT electrode of one of the plurality of series arm resonators closest to the input terminal side in the circuit configuration is divided into three regions in the electrode finger orthogonal direction, an average value of an electrode finger pitch in one central region is smaller than the average value of the electrode finger pitch in two end regions.

19. The multiplexer according to claim 10, wherein the multiplexer is a duplexer, a triplexer, or a quadplexer.

20. A multiplexer comprising:
a plurality of filter devices including at least one reception filter device; wherein
the at least one reception filter device is the filter device according to claim 1.
